(19) United States
(12) Patent Application Publication
(10) Pub. No.: US 2003/0102483 A1
(43) Pub. Date: Jun. 5, 2003

(54) Method of manufacturing optical semiconductor device

(76) Inventors: Toshio Yamamoto, Nagano (JP); Akio Izumi, Nagano (JP); Noriyuki Yaguchi, Nagano (JP); Tomonori Seki, Nagano (JP)

Correspondence Address: KANESAKA AND TAKEUCHI, 1423 Powhatan Street, Alexandria, VA, 22314, US

(21) Appl. No.: 10/307,328

(22) Filed: Dec. 2, 2002

(30) Foreign Application Priority Data
Dec. 4, 2001 (JP) 2001-369852

(51) Int. Cl. H01L 33/00

(52) U.S. Cl. 257/99

(57) ABSTRACT

An optical semiconductor device includes a semiconductor chip, leads electrically connected to the semiconductor chip, and a package through which the leads are projected. In a manufacturing method, a lead frame is formed to have leads and hanging leads that reach the package of the optical semiconductor device. Then, only the leads are cut from the lead frame to form a support frame where the hanging leads support a plurality of the optical semiconductor devices. During the manufacturing process after the support frame is formed, only the support frame is contacted. Therefore, the optical semiconductor devices are processed in a non-contact state during the manufacturing process.

### BACKGROUND OF THE INVENTION AND RELATED ART STATEMENT

The present invention relates to a method of manufacturing an optical semiconductor device, and more particularly relates to a method of manufacturing an optical semiconductor device without contacting an optical semiconductor device with an optical function in a manufacturing process.

In an optical semiconductor device, a light beam must be guided to a light-receiving section on a top surface of a semiconductor chip. Accordingly, a package of the device is provided with an opening or a window at a top surface through which the light is transmitted. A package of a semiconductor device is normally made of an opaque material. However, the optical semiconductor device may have a package specifically formed of a transparent material so as to make an entire package transparent.

Further, to provide more optical functions, some optical semiconductor devices have an additional optical-function element, such as a convex lens, integrally arranged on an entire light-receiving surface. A known example of such an optical semiconductor device includes an image-forming element CCD (charge coupled device), a line sensor (linear image sensor), and distance modules.

A method of manufacturing such an optical semiconductor device will be described next. First, a flat plate is nested to form a lead frame comprising leads and hanging leads. A semiconductor chip is die-bonded and connected to the leads of the lead frame. The semiconductor chip and the leads are electrically connected with wires. Then, the semiconductor chip, the wires, and the leads are molded to form a chip-protecting package.

After the package is formed, the leads can be separated from the lead frame, as the leads are fixed to the package. In this state, the leads are cut to form the package. A transparent plate (or an optical-function element) is arranged at an opening portion of the package as a window, and is then integrated therewith through adhesion. Finally, the hanging leads are cut and separated to complete an individual optical semiconductor device. The optical semiconductor devices are manufactured using this process.

In many cases, the optical-function element or transparent plate in the optical semiconductor device is made of a resin due to an inexpensive cost and easy molding. However, as compared to an optical-function element or transparent plate made of an inorganic material, i.e. a glass, the optical-function element or transparent plate made of a resin is soft and thus easily damaged upon contact with a hard object. In addition, it is difficult to clean, or it is likely to get damaged by cleaning. If there is a stain or flaw on the optical-function element or transparent plate, it is unattractive and its performance may be degraded. Due to these problems, it is difficult to handle these conventional optical semiconductor devices during the manufacturing process. Further, an operator must be very careful when handling these semiconductor devices.

Further, after the package is molded or the hanging leads are cut and separated from the lead frame, the optical semiconductor device must be visually inspected to check a damage, foreign matter such as dust or dirt on the optical-function element or transparent plate, and any missing or bent leads.

During the visual inspection or other operation, due to the above-described problems, the optical semiconductor device must be handled very carefully. Further, it is necessary to provide a container or cushion for pre-caution when the optical semiconductor device is packed, stored, inspected, or transported. Thus, a large amount of time and labor is required to pack such an optical semiconductor device, resulting in low productivity.

The present invention is provided to solve the above-described problems. It is an object of the present invention to provide a method of manufacturing an optical semiconductor device that allows optical semiconductor devices to be handled without being directly contacted, thereby facilitating all handling operations, such as manufacture, packing, storage, inspection, and transportation.

Further objects and advantages of the invention will be apparent from the following description of the invention.

### SUMMARY OF THE INVENTION

To attain the above-described objects, the first aspect of the present invention provides a method of manufacturing an optical semiconductor device. The optical semiconductor device includes a semiconductor chip, leads electrically connected to the semiconductor chip, a package through which the leads are projected, and an optical-function element integrally formed with the package. In the manufacturing method, a lead frame is formed to have leads and hanging leads that reach the package of the optical semiconductor device. Then, only the leads are cut from the lead frame to form a support frame structure where the hanging leads support a plurality of the optical semiconductor devices. During the manufacturing process after the support frame is formed, only the support frame is contacted. Therefore, the optical semiconductor devices are formed in a non-contact state during the manufacturing process.

In the manufacturing method described above, a plurality of completed optical semiconductor devices is mounted on a single support frame. A lead frame for forming the leads is used as the support frame, thereby requiring no additional arrangement and cost compared to a conventional process. Further, the hanging leads supporting the package of the optical semiconductor device are electrically insulated since the package is an insulator. Thus, a damage caused by electrostatic discharge does not need to be considered. The optical semiconductor devices can be manufactured with the support frame gripped and held by an operator or a robot. Consequently, the optical semiconductor devices can be very easily handled during the manufacturing process.

Further, the optical semiconductor devices are handled so that only the support frame is contacted (i.e. the plurality of the optical semiconductor devices is not contacted). Accordingly, the optical semiconductor devices can be handled without paying special attention against any damage, stain or dust in the optical-function element of the optical semiconductor device, or excessive force exerted thereon.

Further, according to the second aspect of the present invention, in addition to the first aspect, a method of manufacturing an optical semiconductor device further includes connection means formed in the support frame for connecting transporting means to the support frame. The support frame and the plurality of the optical semiconductor devices are transported by using the connection means.

In the manufacture method according to the second aspect of the invention, the optical semiconductor devices can be transported via the transportation means that are connected to the connection means formed in the support frame. Consequently, the connection and transportation means can be used in an assembly production line. For example, if the connection means comprises holes and protruding pieces, the transporting means can be composed of projections inserted into the holes or locking members locked to the protruding pieces. Accordingly, it is not necessary to provide large-scale gripping and holding means such as robot hands, thereby further improving the handling.

Further, according to the third aspect of the present invention, in addition to the first and second aspects, a method of manufacturing an optical semiconductor device further includes positioning means formed in the support frame for placing the support frame at a predetermined position. The support frame and the plurality of the optical semiconductor devices are positioned by using the positioning means.

In the manufacture method according to the third aspect of the invention, the plurality of the optical semiconductor devices on the support frame can be placed at a predetermined position by using the positioning means, for example, when the optical semiconductor device are mounted on a circuit board in the manufacturing process.

Further, the fourth aspect of the present invention provides a method of manufacturing an optical semiconductor device, wherein only the support frame formed according to any of the first to third aspects is contacted when the plurality of the optical semiconductor devices is housed, stored, inspected, or transported in a non-contact manner.

In the manufacture method according to the fourth aspect of the invention, the plurality of the optical semiconductor devices is housed, stored, inspected, or transported in a non-contact manner, when an operator holds the optical semiconductor devices with their fingers, a transfer robot grips and holds the optical semiconductor devices, or the optical-semiconductor-device support frame is placed in a container. This prevents the optical-function element from being damaged, stained, or subjected to an excessive force, and eliminates the need to exercise extreme care during the handling.

Further, according to the fifth aspect of the present invention, a method of manufacturing an optical semiconductor device includes the steps of, transporting the optical semiconductor devices with only the support frame in a contacted state, positioning the optical semiconductor devices with only the support frame in the contacted state, mounting the optical semiconductor device with only the support frame in the contacted state, and separating the hanging leads of the support frame from the package, so that the optical semiconductor devices are mounted on and electrically connected to a circuit board in a non-contact manner.

In the manufacture method according to the fifth aspect of the invention, the whole process can be executed in a non-contact manner from the step of moving the plurality of the optical semiconductor devices with the support frame, the step of separating the hanging leads of the lead frame from the package and to the step of mounting the optical semiconductor devices on the circuit board. Further, after the step of mounting, only the circuit boards are contacted when the optical semiconductor devices are handled, so that the optical semiconductor device can still be held in a non-contact state. This facilitates operations by eliminating the need to pay extreme care to the individual optical semiconductor devices during the handling.

### BRIEF DESCRIPTION OF THE DRAWINGS

FIG. 1 is a perspective view showing a support frame on which a plurality of optical semiconductor devices is mounted;

FIGS. 2(a)-2(d) are views showing a configuration of an optical semiconductor device, wherein FIG. 2(a) is a plan view of the optical semiconductor device, FIG. 2(b) is a sectional view taken along line 2(b)-2(b) in FIG. 2(a), FIG. 2(c) is a sectional view taken along line 2(c)-2(c) in FIG. 2(a), and FIG. 2(d) is a sectional view taken along line 2(d)-2(d) in FIG. 2(c);

FIG. 3 is a perspective view showing other type of optical semiconductor device;

FIG. 4 is a perspective view showing other type of optical semiconductor device;

FIGS. 5(a)-5(c) are views showing a magazine in which the optical semiconductor devices are housed, wherein FIG. 5(a) is a perspective view of the magazine, FIG. 5(b) is a front view thereof, and FIG. 5(c) is a side view thereof;

FIGS. 6(a) and 6(b) are views showing a tray in which the optical semiconductor devices are housed, wherein FIG. 6(a) is a perspective view of the tray, and FIG. 6(b) is a sectional view taken along line 6(b)-6(b) in FIG. 6(a); and

FIGS. 7(a)-7(c) are views showing an operation of mounting the optical semiconductor devices on circuit boards, wherein FIG. 7(a) is a perspective view of the operation, FIG. 7(b) is a plan view thereof, and FIG. 7(c) is a side view thereof.

### DETAILED DESCRIPTION OF PREFERRED EMBODIMENTS

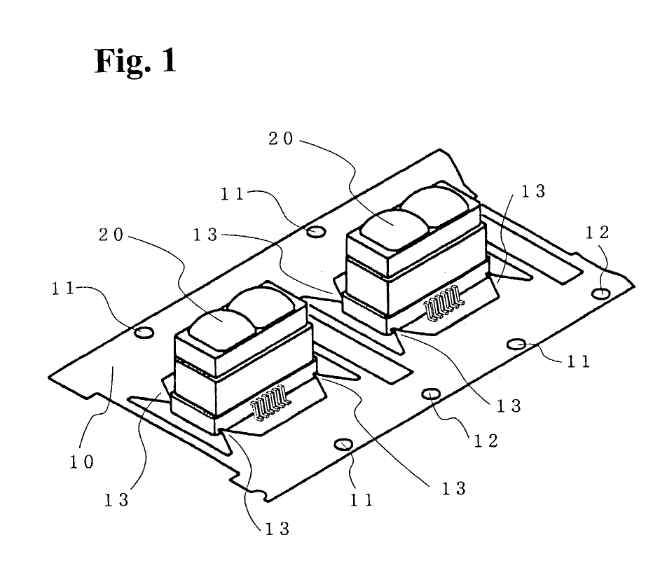

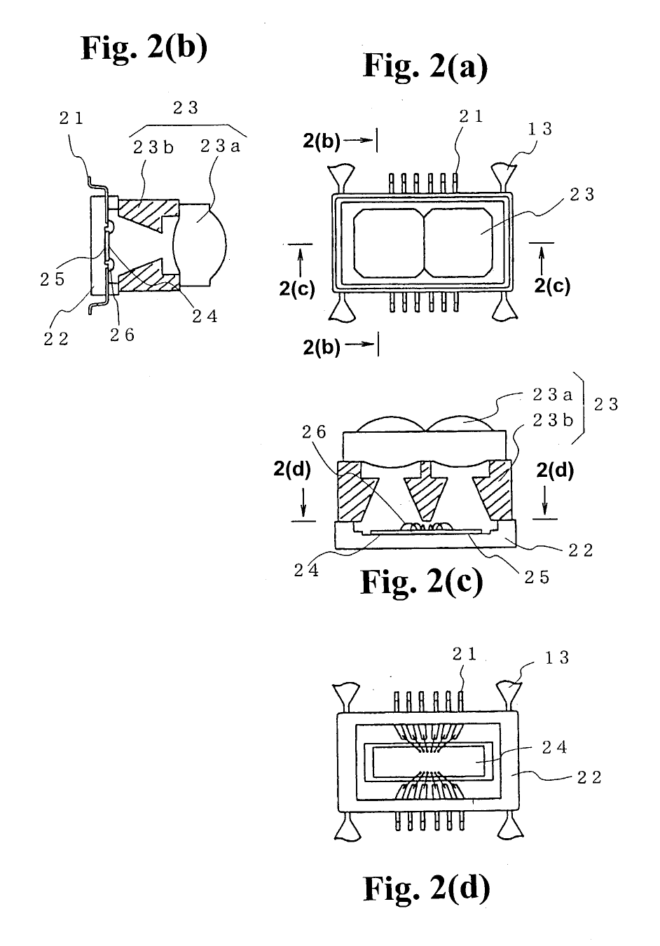

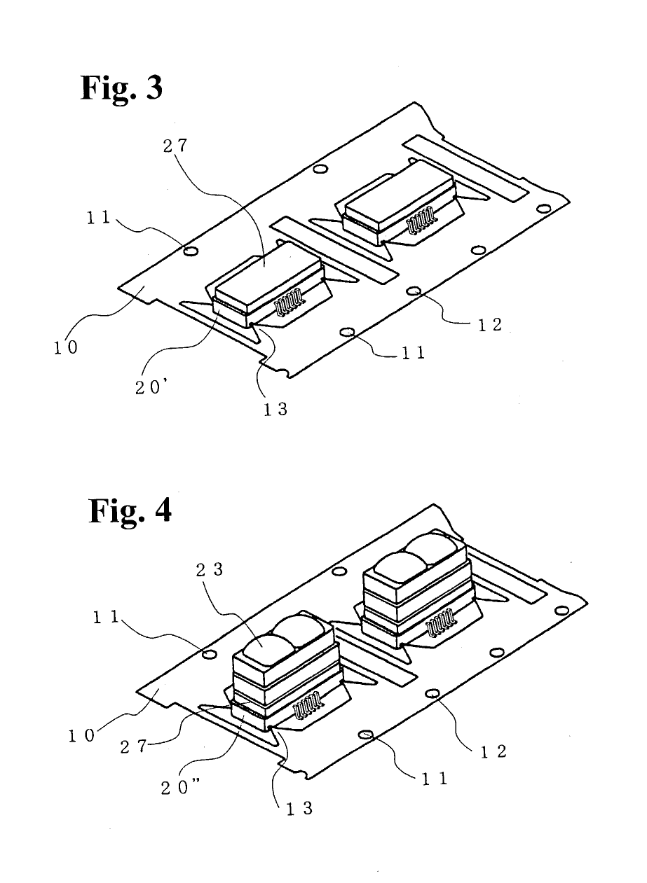

Hereunder, embodiments of the present invention will be described with reference to the accompanying drawings. First, the first embodiment of the present invention will be described. FIG. 1 is a perspective view showing a support frame on which a plurality of optical semiconductor devices is mounted. In FIG. 1, there are two optical semiconductor devices. FIGS. 2(a)-2(c) are views showing a configuration of an optical semiconductor device, wherein FIG. 2(a) is a plan view of the optical semiconductor device, FIG. 2(b) is a sectional view taken along line 2(b)-2(b) in FIG. 2(a), and FIG. 2(c) is a sectional view taken along line 2(c)-2(c) in FIG. 2(a), and FIG. 2(d) is a sectional view taken along line 2(d)-2(d) in FIG. 2(c). FIGS. 3 and 4 are perspective views showing other types of optical semiconductor devices.

In a method of manufacturing an optical semiconductor device according to this embodiment, a lead frame is formed to have leads and hanging leads that reach a package of the optical semiconductor device. Only the leads are cut from the lead frame to form a support frame structure supported by the hanging leads. Thus, the optical semiconductor devices are manufactured in a non-contact manner by subsequently handling the semiconductor devices so that only the support frame is contacted. First, the support frame on which the optical semiconductor devices are formed will be described.

As shown in FIGS. 1 and 2(a)-2(c), the lead frame is used as a support frame 10 comprising reference holes 11 or positioning means, feed holes 12 or connection means, and hanging leads 13. Further, an optical semiconductor device 20 in FIG. 1 comprises leads 21, a package 22, an optical-function element 23, a semiconductor chip 24, an adhesive layer 25, and wires 26, as shown in FIGS. 2(a)-2(c).

The leads 21 are composed of an alloy of iron or copper as a base material. The package 22 is made of a non-transparent resin as a material, and is molded integrally with the leads 21 by an injection molding method, as described later. The optical-function element 23 is composed of a combination of transparent members 23a functioning as a lens and light-blocking members 23b for focusing and blocking a ray bundle. The transparent member 23a is a convex lens made of a transparent resin. The light-blocking member 23b is made of a non-transparent resin, and functions as a diaphragm. The transparent members 23a and the light-blocking members 23b are molded by the injection molding method.

The semiconductor chip 24 has a light-receiving surface shown in FIG. 2(d). The semiconductor chip 24 also has a circuit (not shown) formed therein to provide other functions such as an amplifier, a memory, and an address decoder, for processing signals. The adhesive 25 is composed of, for example, an epoxy resin, and is applied to a die pad section prior to a die bonding process of the semiconductor chip 24. The wires 26 are used to electrically connect an electrode of the semiconductor chip 24 to the lead 21. The wires 26 are composed of gold or aluminum.

Next, both the support frame 10 and optical semiconductor device 20 will be described. The support frame 10, shown in FIG. 1, has feed holes 12 formed therein as connection means to connect the support frame to transporting means (not shown), and the reference holes 11 formed therein as positioning means for positioning the support frame 10 at a predetermined position and providing a reference for mounting the optical semiconductor device 20.

The support frame 10 has the plurality of the optical semiconductor devices 20 arranged thereon and connected thereto via the hanging leads 13. FIG. 1 shows the two optical semiconductor devices 20. However, of course, the number of optical semiconductor devices 20 is not limited to two, and several to several tens of optical semiconductor devices 20 may be arranged on the support frame 10.

The package 22 of each optical semiconductor device 20 has the leads 21 integrated therewith and arranged thereon so as to project therefrom, as shown in FIGS. 2(a)-2(d) . Prior to forming the leads, these leads are fixed to the support frame 10 (the lead frame), and then are cut and separated from the lead frame to be formed.

Furthermore, the support frame 10 is connected to the package 20 via the hanging leads 13. The optical semiconductor device is hung in the air from the support frame 10 by the hanging lead 13. In this manner, the optical semiconductor device is not cut off from the support frame 10, but is combined therewith.

Next, a method of manufacturing such an integrated semiconductor device will be described. First, the lead frame (the support frame 10) is formed so that the leads 21 and the hanging leads 13 reach the package 22 of the optical semiconductor device. Then, the leads 21 are cut from the lead frame to form the support frame on which the optical semiconductor devices are supported by the hanging leads as shown in FIG. 1. Thus, the optical semiconductor devices are manufactured in a non-contact manner by subsequently handling the semiconductor devices so that only the support frame is contacted.

In the optical semiconductor devices, the adhesive layer 25 is applied to a die pad to bond the semiconductor chip 24 to the die, as shown in FIGS. 2(a)-2(d). Further, the semiconductor chip 24 and the leads 21 are electrically connected with the wires 26. The leads 21 are initially integrated with the support frame 10, but are cut and formed in a required form after the package 22 is formed integrally with the support frame 10.

The optical-function element 23 is composed of a combination of the transparent members 23a functioning as a lens and the light-blocking members 23b for focusing and blocking a ray bundle. A position of the optical-function elements 23 is adjusted relative to the package 22 before the optical-function element is combined and integrated with the package by an adhesion.

In the optical semiconductor devices, it is possible to provide modifications, as shown in FIGS. 3 and 4. FIG. 3 is a perspective view showing other type of optical semiconductor device. In optical semiconductor device 20′ shown in FIG. 3, a transparent plate 27 is integrally disposed as a window, instead of the optical-function element 23 of the optical semiconductor device 20 shown in FIGS. 2(a)-2(d). Further, in an optical semiconductor device 20″ shown in FIG. 4, the transparent plate 27 is provided between the package 22 of the optical semiconductor device 20 and the optical-function element 23.

The optical semiconductor devices 20′ and 20″ are hung in the air and held above the support frame 10 via the hanging lead 13. Accordingly, when the optical semiconductor device 20 or 20″ is inspected, the optical semiconductor device 20′ or 20″ can easily be handled without being directly contacted, by gripping and raising the support frame 10. Various forms of optical semiconductor devices other than those described above may be employed.

In the method of manufacturing the optical semiconductor devices using such a support frame, the lead frame (not shown) has the leads 21 and the hanging leads 13 that reach the package of the optical semiconductor devices 20′ or 20″. Only the leads 21 are cut from the lead frame to form the support frame 10 structure supported by the hanging leads 13. Thus, the optical semiconductor devices 20′ or 20″ are manufactured in a non-contact manner by subsequently handling the semiconductor devices so that only the support frame 10 is contacted.

In the method of manufacturing the optical semiconductor device 20′ or 20″, the optical semiconductor devices 20′ or 20″ need not to be contacted for handling during the manufacturing process. This prevents a surface of the transparent member 23a of the optical-function element 23 from being contacted and thus being contaminated or damaged. Further, the leads 21 are prevented from being contacted and thus bent.

The method of manufacturing the optical semiconductor device 20, 20′, or 20″ according to the first embodiment has been described. In this embodiment, the hanging lead 13, a part of the support frame 10, is used to connect the support frame 10 to the optical semiconductor device 20, 20′, or 20″. However, the present invention is not limited to the hanging leads 13, and a connection member may be formed in the package 22 so as to reach the support frame 10 as a hanging lead so that the support frame 10 (lead frame) and the package 22 can be connected when the package 22 is formed. The present invention can attain the objects no matter how the hanging leads are formed as parts of the package 22 or the support frame.

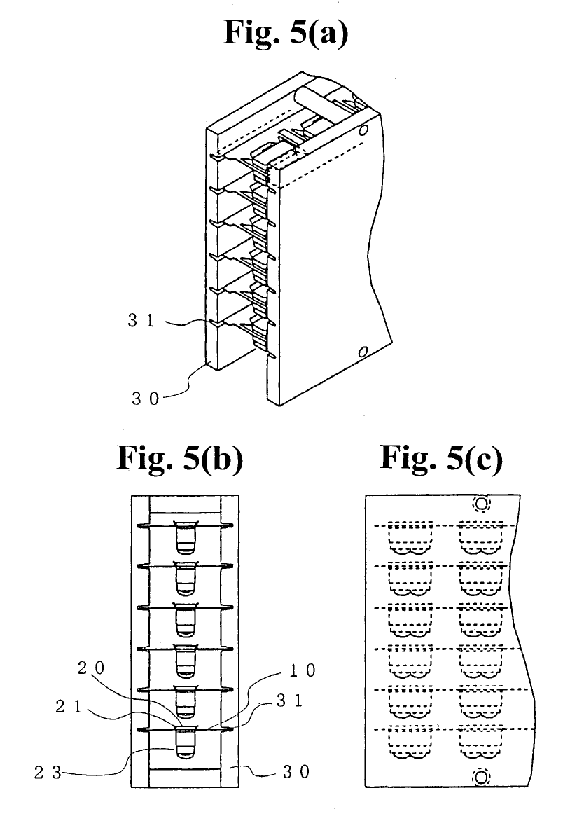

Next, handling procedures of the optical semiconductor devices, including package, storage, inspection, and transportation will be described. FIGS. 5(a)-5(c) are views showing a magazine, in which the optical semiconductor devices are housed, wherein FIG. 5(a) is a perspective view of the magazine, FIG. 5(b) is a front view thereof, and FIG. 5(c) is a side view thereof.

When the optical semiconductor devices 20 integrated with the support frame are housed, a magazine 30 having grooves 31 is used so that only the support frames 10 are contacted with the grooves 31 for support. The grooves 31 in the magazine 30 are formed at a sufficient interval to prevent the optical semiconductor devices 20 from touching each other. Thus, the surface of the optical-function element 23 of the optical semiconductor device 20 is not contacted, and thus not contaminated or damaged.

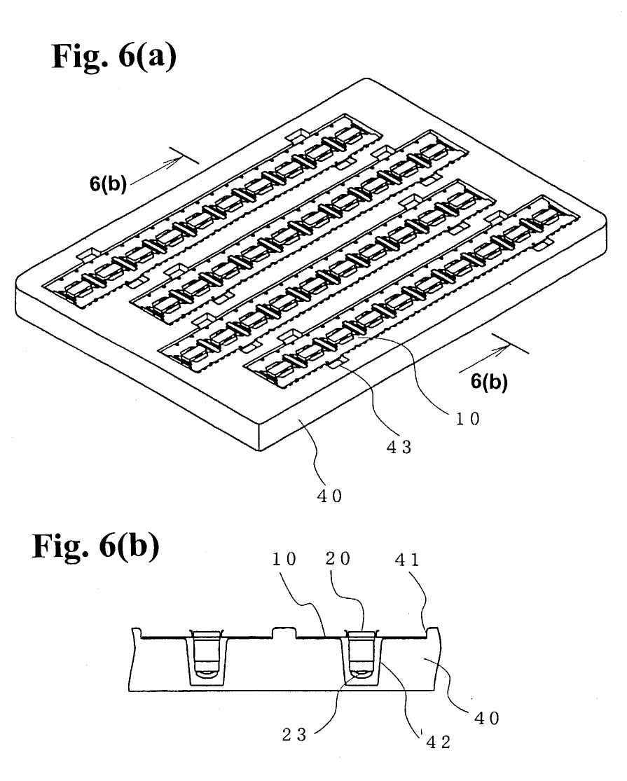

Another housing method will be described with reference to the drawings. FIGS. 6(a) and 6(b) are views showing a tray in which the optical semiconductor devices are housed, wherein FIG. 6(a) is a perspective view of the tray and FIG. 6(b) is a sectional view taken along line 6(b)-6(b) in FIG. 6(a).

A tray 40 has the first recesses 41′ formed in a housing surface thereof. The first recesses 41 are formed in a shallow groove to allow the support frames 10 to be fitted into the recesses. The tray 40 also has the second recesses 42 formed in the housing surface. The second recesses 42 are formed in a deep groove to prevent the optical-function element 23 of the optical semiconductor device 20 from being contacted. The support frame 10 is positioned by sidewalls of the first recess 41, and is supported by a plane of the first recess 41. At this time, an amount of wobbling of the support frame 10 is set such that the optical semiconductor device 20 does not touch a wall of the tray 40 within the second recess 42.

Furthermore, the tray 40 has the third recesses 43 formed therein to allow the support frame 10 to be moved in and out of the tray easily. The sides of the support frame 10 can be held at the third recesses 43.

Once the support frame 10 is housed in the tray 40, the optical semiconductor devices 20 in the tray 40 are held so as to hang in the air via the support frame 10 and the hanging leads 13. This prevents the surface of the transparent member 23a of the optical-function element 23 of the optical semiconductor device 20 from contacting the tray 40 and thus being contaminated or damaged.

Further, the magazine 30, shown in FIGS. 5(a)-5(c), and the tray 40, shown in FIGS. 6(a)-6(b), have an advantage of preventing contaminants from falling onto and depositing on the surface of the optical-function element 23, as the optical-function element 23 is arranged to face downward with only the support frame 10 in contact with the magazine or tray.

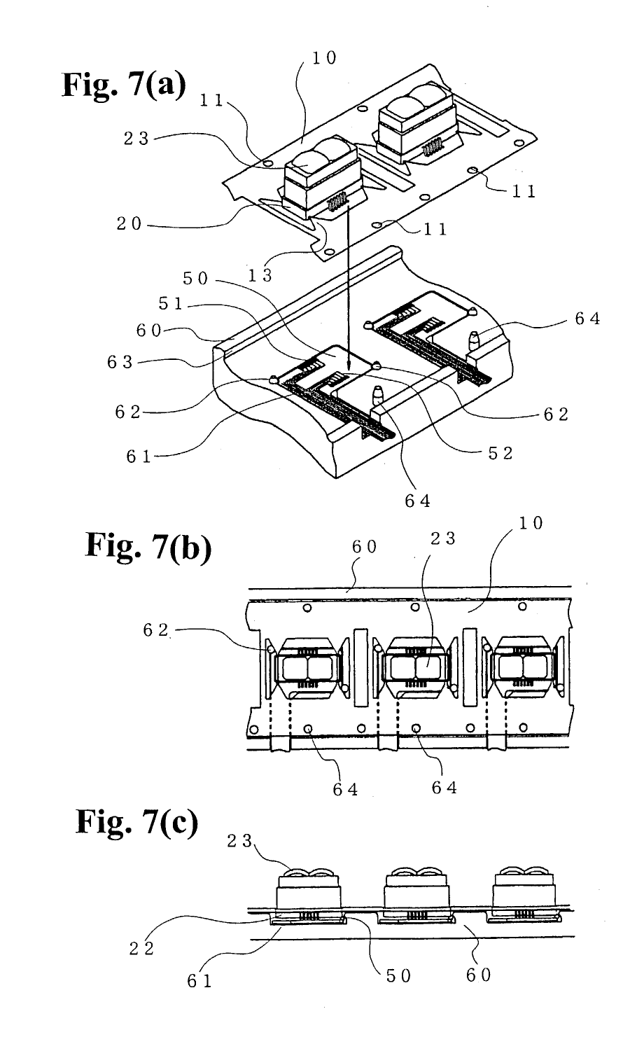

Next, a procedure of mounting the optical semiconductor devices on circuit boards (a method of Mounting an optical semiconductor device on a circuit board and electrically connecting the semiconductor device and the circuit board together) will be described. FIGS. 7(a)-7(c) are views showing the mounting operation, wherein FIG. 7(a) is a perspective view of the operation, FIG. 7(b) is a plan view thereof, and FIG. 7(c) is a side view thereof.

First, the support frame 10 is gripped to transfer the optical semiconductor devices 20. An adjustment jig 60 is provided with circuit-board recesses 61 and guide projections 62 as references for positioning flexible printed circuit boards (hereinafter simply referred to as “circuit boards”) 50 and the support frame 10 and for installing the circuit boards 50. Furthermore, the adjustment jig 60 is provided with a reference recess 63 and guide projections 64 as references for installing the support frame 10 using an outside portion of the support frame 10 and the reference holes 11.

The circuit board 50 is provided with pads 51 connected to the leads 21 of the optical semiconductor device and wires 52 connected to the pads 51. The wires 52, except for the pads 51, are electrically insulated and protected by a thin insulating layer. The circuit board 50 is arranged relative to the adjustment jig 60 by positioning the circuit board 50 using the circuit-board recess 61 and the guide projections 62. Further, the transferred support frame 10 is also arranged relative to the adjustment jig 60 by positioning the support frame using the reference recess 63 and the guide projection 64.

In this case, a relationship between the circuit board 50 placed in the adjustment jig 60 and the optical semiconductor device 20 on the support frame 10 is such that tips of the leads 21 of the optical semiconductor device 20 align with the corresponding pads 51 of the circuit board 50, and surfaces of the leads 21 contact surfaces of the corresponding pads 51 without a space therebetween. Then, the pads 51 of the circuit board 50 are electrically connected to the corresponding leads 21 of the optical semiconductor device 20 using solder or the like. Subsequently, the hanging lead 13, which connects the optical semiconductor device 20 to the support frame 10, is cut to complete the operation of mounting the optical semiconductor device 20 on the circuit board 50.

In this manner, when the optical semiconductor device 20 is transferred and mounted on the circuit board 50, it is possible to handle the device without contacting by gripping the support frame 10. Thus, the optical semiconductor device 20 does not contact even during the mounting operation. Further, the optical semiconductor device 20 can be easily handled without staining or damaging the optical-function element 23.

The positioning structure using the support frame 10 and the positioning structure for the circuit boards 50, described above, are just examples. The present invention is not limited to the shape of the circuit-board recess 61, the positions of the guide projections 62, or the number thereof, as described above. Positioning the optical semiconductor device via the support frame 10 reduces direct contact of the optical semiconductor device 20 during the mounting operation. Further, the optical semiconductor device can be easily handled without staining or damaging the optical-function element 23.

According to the above-described invention, it is possible to conduct such manufacturing processes as forming the package on the lead frame, die-bonding the semiconductor chip, wire-bonding the leads to the semiconductor chip, forming the leads by cutting, and integrating the transparent plate or the optical-function element with the semiconductor device without cutting the semiconductor device off the lead frame.

Further, the present invention is not limited to the optical semiconductor device, and is applicable to semiconductor devices that should avoid direct contact. However, the present invention is most effective in the manufacture of the optical semiconductor devices.

Moreover, the visual inspection or the like can be carried out by gripping the lead frame without directly contacting with the optical semiconductor device. Further, for housing, storage, or transportation, the lead frame can be supported to hold the optical semiconductor device in the air via the hanging lead. Furthermore, when the optical semiconductor device is mounted on and electrically connected to the circuit board, the lead frame can be used to transfer and position the optical semiconductor device. Accordingly, the optical semiconductor device can be mounted without contact.

The above-described configuration reduces the likelihood of direct contact with the optical semiconductor device. This prevents the optical-function element or transparent plate from being stained or damaged, and also prevents the leads from being bent. Therefore, the operations are facilitated to improve yield and efficiency.

In general, the present invention provides the method of manufacturing the optical semiconductor device that allows the optical semiconductor devices to be handled without being directly contacted, thereby facilitating all handling operations, such as manufacturing, housing, storage, inspection, and transportation.

While the invention has been explained with reference to the specific embodiments of the invention, the explanation is illustrative and the invention is limited only by the appended claims.

What is claimed is:

1. A method of manufacturing an optical semiconductor device comprising the steps of:
forming an optical semiconductor device on a lead frame so that the optical semiconductor device is connected to the lead frame through leads and hanging leads,
cutting the leads so that only the hanging leads are connected to the optical semiconductor device to thereby form a support frame in the lead frame, and
processing the optical semiconductor device by holding the support frame without unnecessarily touching the optical semiconductor device in a remaining process of manufacturing the optical semiconductor device.

2. A method of manufacturing the optical semiconductor device according to claim 1, further comprising the step of forming connection means in the support frame for connecting the support frame to transporting means so that the support frame and the optical semiconductor device are transported by the transporting means through the connection means in the remaining process of manufacturing the optical semiconductor device.

3. A method of manufacturing the optical semiconductor device according to claim 1, further comprising the step of forming positioning means in the support frame for placing the support frame and the optical semiconductor device at a predetermined position in the remaining process of manufacturing the optical semiconductor device.

4. A method of manufacturing the optical semiconductor device according to claim 1, further comprising at least one of the steps of housing, storing, inspecting, and transporting the optical semiconductor device without touching the same.

5. A method of manufacturing the optical semiconductor device according to claim 1, wherein said further processing includes the steps of transporting the optical semiconductor device to a circuit board by only holding the support frame, positioning the optical semiconductor device at a predetermined position relative to the circuit board by only holding the support frame, fixing the optical semiconductor device on the circuit board, and cutting the hanging leads so that the support frame is separated from the optical semiconductor device.

6. A method of manufacturing the optical semiconductor device according to claim 1, wherein a plurality of said hanging leads projects toward the semiconductor device to hold the semiconductor device to the support frame.
